(19) United States
(12) Patent Application Publication
(10) Pub. No.: US 2013/0087907 A1
(43) Pub. Date: Apr. 11, 2013

(54) Metal Features to Reduce Crack-Inducing Stresses in Metallization Stacks

(71) Applicants: Matthias U. Lehr, Dresden (DE); Holm Geisler, Dresden (DE); Frank Kuechenmeister, Dresden (DE)

(72) Inventors: Matthias U. Lehr, Dresden (DE); Holm Geisler, Dresden (DE); Frank Kuechenmeister, Dresden (DE)

(73) Assignee: GLOBALFOUNDRIES INC., Grand Cayman (KY)

(21) Appl. No.: 13/253,592

(22) Filed: Oct. 5, 2011

(51) Int. Cl. H01L 23/498; H01L 21/28

(52) U.S. Cl. 257/737; 438/613; 257/E23.068; 257/E21.158

(57) ABSTRACT

Generally, the subject matter disclosed herein relates to sophisticated semiconductor chips that may be less susceptible to the occurrence of white bumps during semiconductor chip packaging operations, such as flip-chip or 3D-chip assembly, and the like. One illustrative semiconductor chip disclosed herein includes, among other things, a bump structure above a first metallization layer of a metallization system of the semiconductor chip, and a metal feature in the first metallization layer, wherein at least a first portion of the metal feature is located closer to a center of the semiconductor chip than any portion of the bump structure, and at least a second portion of the metal feature is positioned below the bump structure.

### BACKGROUND

1. Field of the Disclosure

Generally, the present disclosure relates to sophisticated semiconductor devices, and, more particularly, metal features that are adapted to at least reduce the level of crack-inducing stresses induced in a metallization stack of a semiconductor chip during the chip/carrier packaging process.

2. Description of the Related Art

In the manufacture of modern integrated circuits, it is usually necessary to provide electrical connections between the various semiconductor chips making up a microelectronic device. Depending on the type of chip and the overall device design requirements, these electrical connections may be accomplished in a variety of ways, such as, for example, by wirebonding, tape automated bonding (TAB), flip-chip bonding, and the like. In recent years, the use of flip-chip technology, wherein semiconductor chips are attached to carrier substrates, or to other chips, by means of solder balls formed from so-called solder bumps, has become an important aspect of the semiconductor processing industry. In flip-chip technology, solder balls are formed on a contact layer of at least one of the chips that is to be connected, such as, for example, on a dielectric passivation layer formed above the last metallization layer of a semiconductor chip comprising a plurality of integrated circuits. Similarly, adequately sized and appropriately located bond pads are formed on another chip, such as, for example, a carrier package, each of which corresponds to a respective solder ball formed on the semiconductor chip. The two units, i.e., the semiconductor chip and carrier substrate, are then electrically connected by “flipping” the semiconductor chip and bringing the solder balls into physical contact with the bond pads, and performing a “reflow” process so that each solder ball bonds to a corresponding bond pad. Typically, hundreds of solder bumps may be distributed over the entire chip area, thereby providing, for example, the I/O capability required for modern semiconductor chips that usually include complex circuitry, such as microprocessors, storage circuits, three-dimensional (3D) chips, and the like, and/or a plurality of integrated circuits forming a complete complex circuit system.

In many processing applications, a semiconductor chip is bonded to a carrier substrate during a high temperature so-called Controlled Collapse Chip Connection (C4) solder bump reflow process. Typically, the substrate material is an organic laminate, which has a coefficient of thermal expansion (CTE) that may be on the order of 4-5 times greater than that of the semiconductor chip, which, in many cases, is made up primarily of silicon and silicon-based materials. Accordingly, due to the coefficient of thermal expansion mismatch between the chip and the substrate (i.e., silicon vs. organic laminate), the substrate will grow more than the chip when exposed to the reflow temperature, and as a consequence, stresses will be imposed on the chip/substrate package as the package cools and the solder bumps solidify. FIGS. 1a-1c, which schematically illustrate at least some of the possible effects that may occur on a chip package during this process, will now be described.

FIG. 1a schematically illustrates a chip package 100, which includes a carrier substrate 101 and a semiconductor chip 102. The semiconductor chip 102 typically comprises a plurality of solder bumps 103, which are formed above a metallization system 104 (see FIG. 1c) of the chip 102. During the chip packaging assembly process, the semiconductor chip 102 is inverted, or “flipped,” and brought into contact the carrier substrate 101, after which the chip package 100 of FIG. 1a is exposed to a solder bump reflow process 120 at a reflow temperature that exceeds the melting temperature of the solder bump material. Depending on the specific solder alloy used to form the solder bumps 103, the reflow temperature may be upwards of 200°-265° C. During the reflow process 120, when the material of the solder bumps 103 is in a liquid phase, both the carrier substrate 101 and the semiconductor chip 102 are able to thermally “grow” in a substantially unrestrained manner, based on the respective coefficient of thermal expansion of each component. As such, both the carrier substrate 101 and the semiconductor chip 102 remain in an essentially flat, non-deformed condition, although each will grow by a different amount due to their different coefficients of thermal expansion.

FIG. 1b, on the other hand, schematically illustrates the chip package 100 during a cool-down phase, when a thermal interaction begins to take place between the carrier substrate 101 and the semiconductor chip 102. As the chip package 100 cools, the solder bumps 103 solidify and mechanically join the package substrate 101 to the semiconductor chip 102. As the chip package 100 continues to cool after solder bump 103 solidification, the CTE mismatch between the materials of the carrier substrate 101 and the semiconductor chip 102 cause the substrate 101 to shrink at a greater rate than the chip 102. Typically, this difference in thermal expansion/contraction is accommodated by a combination of out-of-plane deformation of both the carrier substrate 101 and the semiconductor chip 102, and some amount of shear deformation of the solder bumps 103. This out-of-plane deformation induces a shear and bending forces 101F, 101M in the carrier substrate 101, as well as shear and bending forces 102F, 102M in the semiconductor chip 102. Other localized effects may occur in the semiconductor chip 102 in areas immediately surrounding the solder bumps 103, as illustrated in FIG. 1d and described below.

FIG. 1c schematically illustrates a plan view of the semiconductor chip 102 of FIGS. 1a-1b. As shown in FIG. 1c, the semiconductor chip 102 has a center 102C located at the intersection of an first chip centerline 102X and a second chip centerline 102Y of the chip 102. Additionally, a plurality of solder bumps 103 may be distributed over the surface of the semiconductor chip 102. It should be noted, however, that the solder bumps 103 shown in FIG. 1c are depicted as being randomly positioned, but it should be appreciated that the relative positions of the solder bumps 103 are illustrative only, as the bumps 103 may generally be distributed in a substantially uniform or homogeneous fashion, at least locally, over the surface of the semiconductor chip 102. Furthermore, the schematically depicted shear force 102F that may be induced in semiconductor chip 102 as a result of the thermal interaction between the chip 102 and the carrier substrate 101 (see, FIG. 1b) will generally be oriented from the periphery 102P of the semiconductor chip 102 toward, or in the general direction of, the center 102C, as indicated by the arrows shown in FIG. 1c.

FIG. 1d schematically illustrates an area of the semiconductor chip 102 surrounding an individual solder bump 103A after cool-down of the chip package 100. For simplicity, the semiconductor chip 102 has been inverted relative to the chip packaging configurations illustrated in FIGS. 1a-1b, and the carrier substrate 101 is not shown. Furthermore, only the uppermost metallization layers 104A, 104B and 104C of a metallization system 104 of the semiconductor chip 102 are shown in FIG. 1d, and any metallization layers below layer 104C, device layers, or substrate layers of the chip 102 have not been depicted. The semiconductor chip 102 may include a passivation layer 106 formed above the last metallization layer 104A, an underbump metallization (UBM) layer 105U formed in and above an opening in the passivation layer 106, and a solder bump 103A formed above the UBM layer 105U. In some cases, the solder bump 103A may facilitate the creation of an electrical connection between the carrier substrate 101 (not shown in FIG. 1d) and one or more semiconductor devices (not shown) formed in the device level (not shown) of the semiconductor chip 102. However, in other cases, the solder bump 103A may be a “dummy bump” that does not provide an electrical connection to chip circuitry (not shown), but wherein the “dummy bump” is included so as to provide the substantially uniform or homogeneous bump distribution previously noted.

When the solder bump 103A is intended to provide an electrical connection to chip circuitry (not shown in FIG. 1d), the UBM layer 105U and the solder bump 103A may be formed above a bond pad 105, which may be used to facilitate an electrical connection to an underlying contact structure 107. Both the bond pad 105 and the contact structure 107 shown in FIG. 1d are outlined with dotted lines, indicating that these elements may or may not be present below the solder bump 103A. As noted previously, the bond pad 105 (when present) may be in contact with the contact structure 107 so as to facilitate the electrical connection of the solder bump 103A to an integrated circuit (not shown) formed in the device level (not shown) below the metallization system 104. For illustrative purposes only, the contact structure 107 (when present) may include, for example, a contact via 107B formed in the metallization layer 104B, a conductive line 107C and a contact via 107D in the metallization layer 104C, and the like, whereas other configurations may also be used.

As noted above, during the cool-down phase, the out-of-plane deformation of the chip package 100 that is caused by the thermal interaction of the semiconductor chip 102 and the carrier substrate 101 will typically induce shear and bending loads 102F, 102M in the chip 102. These shear and bending loads 102F, 102M will result in local forces acting on each solder bump 103, such as the shear force 103F and bending moment 103M across the solder bump 103A. However, since the solder material is, in general, very robust, and typically has a strength that exceeds that of the materials that make up the semiconductor chip 102—and in particular, the metallization system 104—relatively little deformation energy will be absorbed by the solder bump 103A. Instead, the majority of the loads 103F and 103M will be translated through the solder bump 103A and into the metallization layers, such as layers 104A-104C, underlying the solder bump 103A. These translated loads will generally have the highest magnitude in an area of the metallization system 104 that is below the edges 113 (shown in FIG. 1d as a dotted line) of the solder bump 103A.

Under the conditions outlined above, highly localized stresses may develop in one or more of the metallization layers of the metallization system 104, such as a tensile stress 108T on one side of the solder bump 103A and a compressive stress 108C on the opposite side of the solder bump 103A. Furthermore, if the stresses 108T and/or 108C are of a high enough magnitude, a local failure of one or more of the metallization layers may occur below the solder bump 103A. Typically, a failure of a given metallization layer will manifest as a delamination or a crack 109, and will normally occur where the loads are highest—i.e., near the edges 113 of the solder bump 103A, as shown in FIG. 1d. In some cases, the crack 109 may only occur in a single metallization layer, such as the layer 104C shown in FIG. 1c, whereas in other cases, and depending on many factors, the crack 109 may propagate either deeper or shallower into the underlying metallization system 104, e.g., spreading from one metallization layer to another.

Delamination failures and cracks, such as the crack 108, that may occur in a metallization layer below a solder bump 103 are sometimes subject to premature failure, as the solder bump 103 may not make a good electrical connection to the contact structures below. However, since the delamination/crack defects described above do not occur until the chip packaging assembly stage of semiconductor chip manufacture, the defects will generally not be detected until a final quality inspection is performed. In some cases, after the flip-chip operation has been completed, the chip package 100 may be subjected to acoustic testing, such as C-mode acoustic microscopy (CSAM). Cracks 109 that may be present in the metallization system 104 of the semiconductor chip 102 below the solder bumps 103 will have a white appearance during the CSAM inspection process, and are therefore sometimes referred to as “white bumps,” “white spots,” or “ghost bumps.” White bump defects may impose a costly downside to the overall chip manufacturing process, as they do not occur, and hence cannot be detected, until a significant material and manufacturing investment in the chip has already occurred. Furthermore, in those instances where the assembled chip package 100 is not subjected to CSAM inspection, undetected white bump defects may lead to reduced overall device reliability.

Moreover, recent changes and advances in the types of materials used in sophisticated semiconductor devices have also had an impact on the frequency in which white bumps occur. For example, for many years, the materials used for forming solder balls used in flip-chip technology included any one of a variety of so-called tin/lead (Sn/Pb) solders. Typically, the alloys that were used for most Sn/Pb solders have a level of ductility that enabled the Sn/Pb solder bumps to deform under the loads induced during the cool-down phase of the solder bump reflow process, thereby absorbing some of the out-of-plane deformation energy discussed above. However, in recent years, industries have generally moved away from the use of Sn/Pb solders in most commercial applications, including semiconductor processing. Accordingly, lead-free soldering materials, such as Sn/Ag (tin-silver), Sn/Cu (tin-copper), Sn/Ag/Cu (tin-silver-copper, or SAC) solders, and the like, have been developed as substitute alloys for forming solder bumps on semiconductor chips. These lead-free substitute soldering materials generally have a higher material strength and lower ductility than most of the commonly-used Sn/Pb solders, and also typically require higher temperatures for reflow. As such, less deformation energy is absorbed by lead-free solder bumps, and a commensurately higher loading is imparted on the metallization system underlying the solder bumps, which may subsequently lead to the occurrence of white bump defects, as previously described.

Additionally, the development and use of dielectric materials having a dielectric constant (or k-value) of approximately 3.0 or lower—which are often referred to as “low-k dielectric materials”—has led to an increased incidence of white bumps. Typically, low-k dielectric materials have lower mechanical strength, mechanical modulus, and adhesion strength than do some of the more commonly used dielectric materials having higher k-values, such as silicon dioxide, silicon nitride, silicon oxynitride, and the like. As metallization systems utilize more metallization layers that are made up of low-k dielectric materials, there is a greater likelihood that the lower strength low-k materials will rupture when exposed to the loads that are imposed on the metallization layers underlying the solder bumps, thus leading to delaminations and cracks—i.e., white bump defects. In particular, cracks tend to occur, or at least initiate, in the low-k metallization layers that are closest to the upper surface of the a semiconductor chip—i.e., closest to the last metallization layer—as the deformation energy is greatest near the upper surface, and lessens in lower metallization levels. Furthermore, it appears that the type of white bump problems described above are even further exacerbated in metallization layers comprised of ultra-low-k (ULK) materials having k-values of approximately 2.7 or lower.

It should be noted that, while FIGS. 1a-1d describe typical white bump problems that may be associated with flip-chip packaging problems, the issues identified above are equally applicable to other chip package configurations, such as 3D-chips and the like. Furthermore, white bump problems are not only limited to chip packaging connections that are made using traditional solder ball bump structures. For example, the thermal interactions described above may also occur when other types of bump structures, such as pillar bump structures, are used to facilitate the electrical connections between the semiconductor chip 102 and the carrier substrate 101. Pillar bump structures, also sometimes referred to as post bump structures, are typically made up of a highly conductive metal, such as copper, gold, silver and the like, or alloys thereof, which may provide certain advantages over traditional solder ball bump structures. For example, pillar bumps may permit a higher standoff between the chip and the substrate, thereby facilitating easier underfilling after the bonding operation. Furthermore, highly conductive pillar bumps, such as copper pillar bumps, may also provide better overall thermal and/or electrical performance. However, pillar bump structures generally also include small solder caps, which, as with the solder ball bump structures described above, must also be exposed to a high temperature reflow process so as to provide the final electrical connection to a carrier substrate, during which time the above-described thermal interactions will occur.

Accordingly, and in view of the foregoing, there is a need to implement new design strategies to address the manufacturing issues associated with white bumps that occur during typical chip packaging operations. The present disclosure relates to process device designs and methods that are directed to avoiding, or at least mitigating, the effects of one or more of the problems identified above.

### SUMMARY OF THE DISCLOSURE

The following presents a simplified summary of the present disclosure in order to provide a basic understanding of some aspects disclosed herein. This summary is not an exhaustive overview of the disclosure, nor is it intended to identify key or critical elements of the subject matter disclosed here. Its sole purpose is to present some concepts in a simplified form as a prelude to the more detailed description that is discussed later.

Generally, the subject matter disclosed herein relates to sophisticated semiconductor chips that may be less susceptible to the occurrence of white bumps during semiconductor chip packaging operations, such as flip-chip or 3D-chip assembly, and the like. One illustrative semiconductor chip disclosed herein includes, among other things, a bump structure above a first metallization layer of a metallization system of the semiconductor chip, and a metal feature in the first metallization layer, wherein at least a first portion of the metal feature is located closer to a center of the semiconductor chip than any portion of the bump structure, and at least a second portion of the metal feature is positioned below the bump structure.

In another illustrative embodiment of the present subject matter, a semiconductor chip includes a first metallization layer of a metallization system of the semiconductor chip, the first metallization layer including a metal feature, and the metal feature having an edge that is a first distance from a centerline of the semiconductor chip. Additionally, the disclosed semiconductor chip includes a second metallization layer of the metallization system, wherein the second metallization layer is below the first metallization layer, and the second metallization layer is made up of a low-k dielectric material having a dielectric constant of approximately 3.0 or lower. Furthermore, the semiconductor chip also includes, among other things, a bump structure above a last metallization layer of the metallization system, wherein the last metallization layer is above the first metallization layer, the bump structure is positioned above at least a portion of the metal feature, the bump structure having an edge that is a second distance from the centerline, wherein the first distance is less than the second distance.

Also disclosed herein is an illustrative method that includes, among other things, forming a metal feature in a first metallization layer of a metallization system of a semiconductor chip, wherein the metal feature has an edge that is a first distance from a centerline of the semiconductor chip. Furthermore, the disclosed method also includes forming a bump structure above a last metallization layer of the metallization system, wherein the bump structure is formed above at least a portion of the metal feature and has an edge that is a second distance from the centerline that is greater than the first distance.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate a flip-chip packaging operation of a semiconductor chip and a carrier substrate;

FIG. 1c schematically illustrates a plan view of the semiconductor chip of FIGS. 1a-1b;

FIG. 1d schematically illustrates out-of-plane loading on a solder ball and metallization system of a semiconductor chip after the flip-chip packaging operation of FIGS. 1a-1b;

FIG. 2a schematically illustrates a plan view of a semiconductor chip in accordance with one illustrative embodiment of the present disclosure;

FIGS. 2b-2e schematically illustrate a spatial relationship between metal lines of a metallization system and a bump structure of a representative prior art semiconductor device;

FIG. 2f-2i schematically illustrate a spatial relationship between metal lines and metal features of a metallization system and a bump structure in accordance with one illustrative embodiment of the present disclosure; and

FIGS. 2j-2k schematically illustrate a spatial relationship between metal features of a metallization system and a bump structure in accordance with another illustrative embodiment of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In general, the presently disclosed subject matter is directed to semiconductor chips wherein a metal feature may be formed in the metallization layers of the chip metallization system, and which is positioned and sized so as to reduce, or at least mitigate, the occurrence of white bumps caused by the differential thermal expansion effects imposed on the metallization layers of the semiconductor chip during chip packaging operations. The metal features disclosed herein may, in certain embodiments, act to distribute the loads that are imparted on the metallization system, so that the localized stresses that sometimes occur below an edge of a bump structure, such as a solder bump or a pillar bump, may be spread out over a larger area, and have a commensurately smaller magnitude.

In some illustrative embodiments, the metal features of the present disclosure may be formed below and in the vicinity of bump structures that are located in areas of a semiconductor chip that are typically exposed to the highest out-of-plane loads caused by the CTE (coefficient of thermal expansion) mismatch between the semiconductor chip and the carrier substrate. Accordingly, such metal features may aid in reducing the magnitude of the crack-inducing stresses and induced in the metallization layers underlying a given bump structure. For example, since the size of a body—i.e., its length or width—is one factor that may have a significant effect on the total amount of thermal expansion that body undergoes when exposed to an elevated temperature, the points of greatest thermal interaction may occur in those areas of the semiconductor chip which are farthest from a neutral center, or centerline, of the chip. Accordingly, in certain embodiments, at least some of the metal features may be located below and/or near bump structures that may be located in one or more of the corner regions of the semiconductor chip, where the differential thermal expansion problems discussed above may be the greatest. Moreover, these metal features may be of particular importance when the affected metallization layers below the metal features are made up of low-k and/or ultra-low-k (ULK) dielectric materials, both of which generally have substantially reduced mechanical strength as compared to typical oxide or nitride dielectrics.

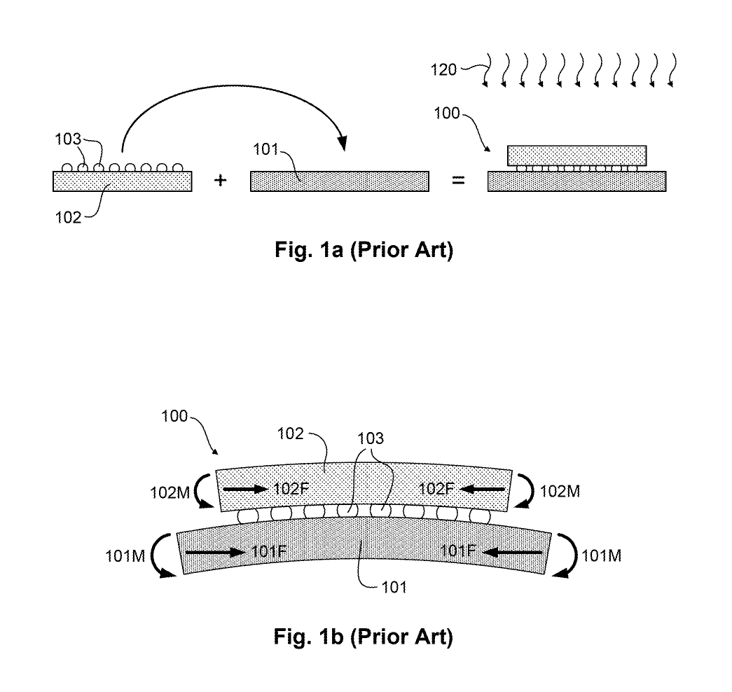

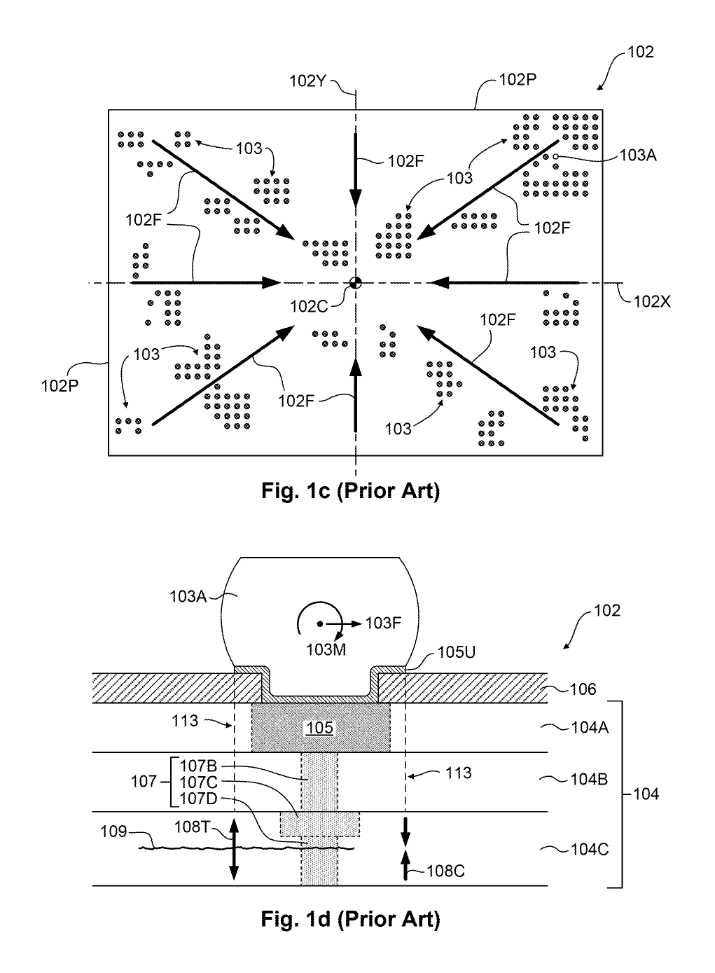

It should be understood that, unless otherwise specifically indicated, any relative positional or directional terms that may be used in the descriptions below—such as “upper,” “lower,” “on,” “adjacent to,” “proximate,” “above,” “below,” “over,” “under,” “top,” “bottom,” “vertical,” “horizontal,” and the like—should be construed in light of that term's normal and everyday meaning relative to the depiction of the components or elements in the referenced figures. For example, referring to the schematic cross-section of the semiconductor chip 102 depicted in FIG. 1c, it should be understood that the passivation layer 106 is formed “above” the last metallization layer 104A, and the bond pad 105 is positioned “below” or “under” the solder bump 103A. Similarly, it should also be noted that the passivation layer 106 may be positioned “on” the last metallization layer 104A in those embodiments wherein no other layers or structures are interposed therebetween. On the other hand, it should be appreciated that the solder bump 103A may not be “on” the bond pad 105 in those instances where the UBM layer 105U is present therebetween.

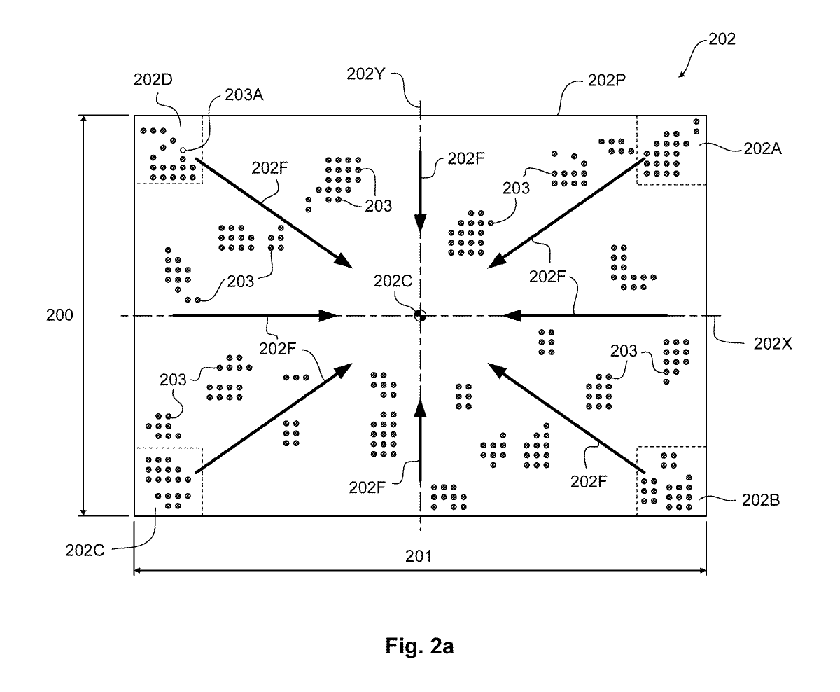

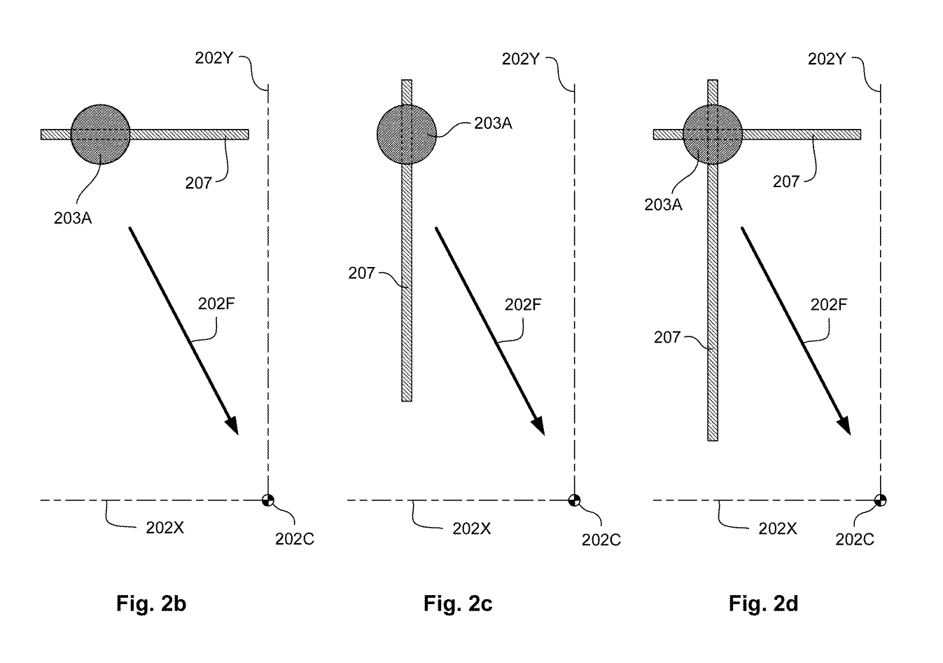

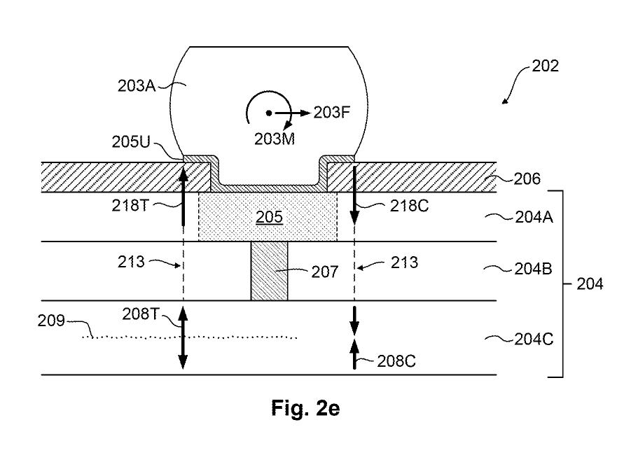

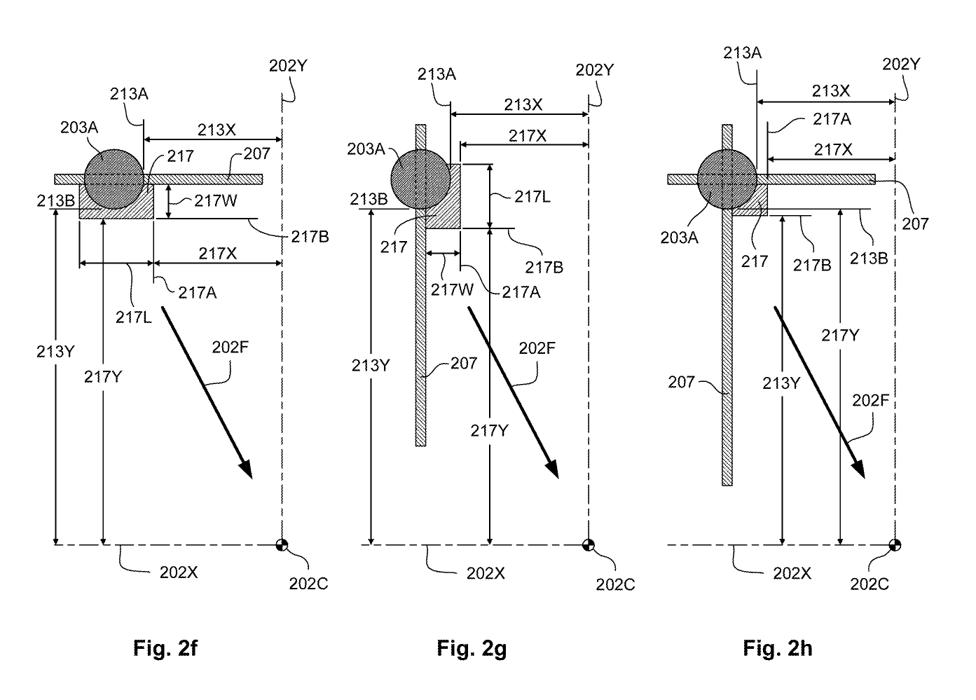

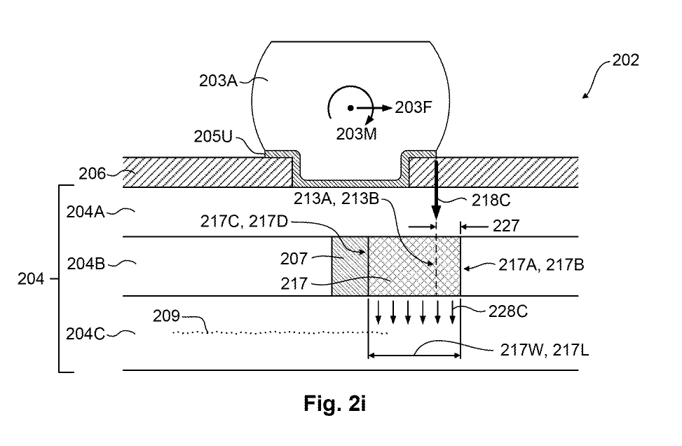

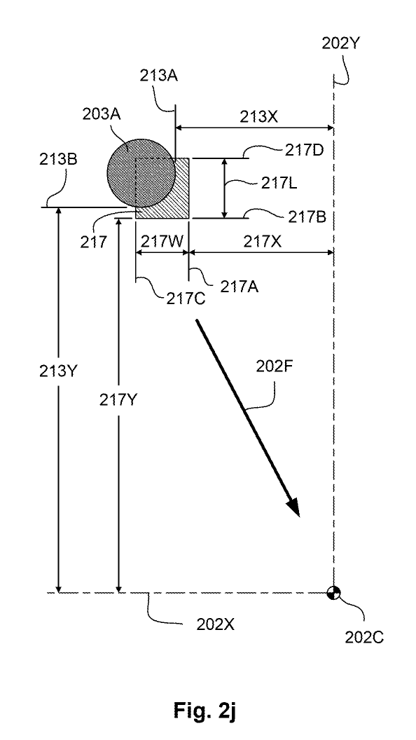

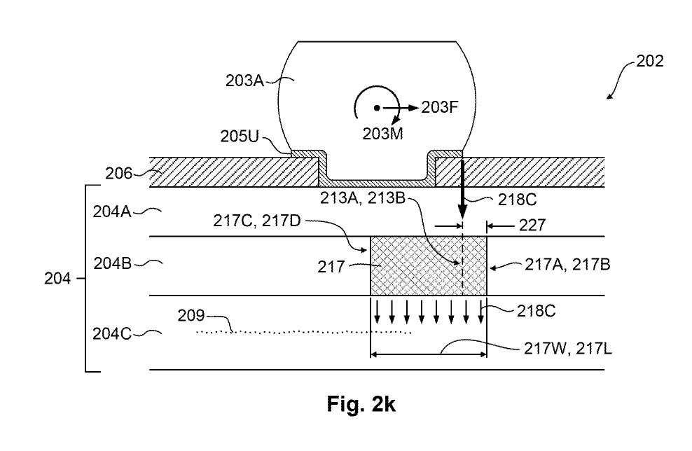

FIG. 2a schematically depicts a plan view of an illustrative embodiment of a semiconductor chip 202 in accordance with one illustrative embodiment of the present disclosure. The semiconductor chip 202 may have a substantially rectangular configuration, having a chip length 201 and a chip width 200, as well as a chip center 202C through which runs a first chip centerline 202X that is substantially parallel to the chip length 201 and a second chip centerline 202Y that is substantially parallel to with the chip width 200. Depending on the specific application, the chip length and width dimension 201, 200 of the semiconductor chip 202 may range from approximately 0.5 cm up to approximately 2.5 cm or even larger. It should be noted that the chip length 201 and chip width 200 need not have the same dimensions, although they may in some embodiments. In certain illustrative embodiments, the semiconductor chip 202 may include a plurality of bump structures 203 that are generally distributed over the surface of the chip 202. Furthermore, it should be understood that the semiconductor chip 202 may be assembled in a chip package using a flip-chip operation, much as described above with respect to the semiconductor chip 102 of the chip package 100 and illustrated in FIGS. 1a-1b, although other assembly techniques may also be employed. Accordingly, as noted with respect to the semiconductor chip 102 above, a shear force 202F that may be induced in semiconductor chip 202 as a result of the thermal interaction between the chip 202 and a carrier substrate (not shown; see, e.g., FIG. 1b) will generally be oriented from the periphery 202P of the semiconductor chip 202 toward the center 202C, as indicated by the arrows shown in FIG. 2a.

In certain illustrative embodiments of the present disclosure, the bump structures 203 may be arranged on the semiconductor chip 202 in a substantially square or rectangular grid-like pattern, so as to facilitate the photolithography patterning processes that may be used to pattern the various material layers used to form the bump structures 203, such as a final metallization layer, passivation layer, UBM layer, and the like. Moreover, depending on the device design and layout requirements, the spacing and/or density of the grid-like pattern may vary from area to area over the semiconductor chip 202, or the grid-like pattern may continue substantially uninterrupted over the entirety of the chip 202, as may be necessary to facilitate the overall uniformity of the plating and UBM etch processes.

As shown in FIG. 2a, at least some of the bump structures 203 may be located in the corner regions 202A-D of the semiconductor chip 202—i.e., in those areas of the chip 202 where chip package thermal interactions are typically highest, and where the likelihood of white bump occurrences may be greatest, as previously discussed. Accordingly, after having reviewed the full description and details of the present disclosure, it may be appreciated by a person of ordinary skill that it may be advantageous to utilize the metal features disclosed herein in a metallization layer below and/or near one or more of the bump structures 203 that are positioned proximate the corners of the semiconductor chip 202—i.e., in one of the corner regions 202A-D. For example, the corner regions 202A-D may be defined as those areas of the semiconductor chip 202 that are within a distance from each of the corners of the chip 202 of approximately 20% of the chip length 201 along the length direction and 20% of the chip width 200 along the width direction. In that regard, the spatial relationship between the metal features of the present disclosure and a representative bump structure 203 located proximate a corner of the semiconductor chip 202, such as, for example, the bump structure 203A located in the corner region 202D, will hereinafter be described in detail.

FIGS. 2b-2d schematically illustrate various plan views of some typical configurations of a representative bump structure 203A and one or more metal lines 207 in a metallization layer (not shown) below the bump structure 203A. It should be appreciated that the metal lines 207 may represent any one of the numerous conductive lines that may be used to form the circuit layout (not shown) of one or more of semiconductor devices (not shown) of the semiconductor chip 202, and which may be routed in any number of ways, depending on the device processing requirements and overall chip design. For example, as shown in FIG. 2b, the metal line 207 may be positioned in a metallization layer below the bump structure 203A (as indicated by the dotted lines) and oriented to run in a direction that is substantially parallel to the chip centerline 202X of the semiconductor chip 202. On the other hand, the metal line 207 may be positioned below the bump structure 203A and oriented such that it runs substantially parallel to the chip centerline 202Y as shown in FIG. 2c—i.e., substantially perpendicular to the chip centerline 202X. Furthermore, in some instances, there may be two lines positioned below the bump structure 203A, with one each oriented parallel to the chip centerlines 202Y and 202X, as shown in FIG. 2d. In any case, it should be appreciated that, in light of the thermal interaction between the semiconductor chip 202 and a carrier substrate (not shown) caused by the differential thermal expansion during the bump reflow process, the bump structure 203A will be exposed to a schematically depicted shear force 202F, which, as previously explained, may be substantially oriented toward, or in the general direction of, the center 202C of the chip 202 (see, FIG. 2a).

FIG. 2e schematically depicts a representative cross-section of at least one of the bump structure 203A and metal line 207 configurations illustrated in FIGS. 2b-2d. As shown in FIG. 2e, the metal line 207 may be located in a metallization layer 204B that is below the last metallization layer 204A of a metallization system 204. Furthermore, the metal line 207 may also be positioned below a contact pad 205, which, in certain instances, may be adapted to provide an electrical connection to the bump structure 203A. In other instances, however, the metal line 207 may not be in electrical contact with the contact pad 205, as the metal line 207 may be positioned in a metallization layer that is two or more layers below the contact pad 205. In still other instances, the bump structure 203A may be a “dummy” bump structure, which are bump structures that may sometimes be included in the overall bump structure layout of the semiconductor chip 202 so as to provide the substantially uniform bump distribution previously described, but which are not electrically connected to any of the circuitry of the chip 202. In those instances where the bump structure 203A is a “dummy” bump structure, the contact pad 205 may not be present in the last metallization layer 204A, and accordingly, the contact pad 205 is outlined in dotted lines, indicating that it may or may not be present in the structure shown in FIG. 2e.

As noted above, the loads 203F and 203M induced on the bump structure 203A will be translated through the bump structure 203A and into the underlying metallization layers 204A-204C. Furthermore these loads will generally have their highest magnitude in an area of the metallization system 204 that is below the edges 213 (shown in FIG. 2e as a dotted line) of the bump structure 203A, such as an uplift, or tension, load 218T on one side of the bump structure 203A, and a downward, or compressive, load 218C on the opposite side of the bump structure 203A.

In many instances, the uppermost few metallization layers of the metallization system 204, such as, for example, the metallization layers 204A and 204B, may be made up of what are considered to be more “traditional” silicon-based dielectric materials, such as silicon dioxide, silicon oxynitride, silicon nitride, silicon-carbon-nitride, and the like, which generally have dielectric constants in excess of approximately 3.5. These traditional dielectric materials may also have a sufficiently robust mechanical strength to withstand the loads 218T, 218C that may typically be encountered during the chip packaging process without resulting in a delamination or crack-like failure, as previously described. However, in most modern applications, many of the remaining underlying metallization layers, such as the metallization layer 204C and layers therebelow (not shown) may be made up of low-k and ULK materials, which typically have a much lower mechanical strength than traditional dielectric materials. Accordingly, while the traditional dielectric materials of the uppermost few metallization layers 204A and 204B may have a great enough mechanical strength to withstand the loads 218T, 218C imposed by the bump structure 203A, the stresses 208T and/or 208C that are induced by the loads 218T, 218C in the low-k or ULK metallization layer 204C may lead to a typical white bump failure, such as the illustrative and schematically depicted crack 209, shown as a dotted line FIG. 2e.

FIGS. 2f-2h, which schematically depict various illustrative embodiments of the spatial relationship between the metal lines 207 and metal features 217 of a metallization system (not shown) and a representative bump structure 203A in accordance with the present disclosure, will now be described.

It should be noted that the plan views schematically shown in FIGS. 2f-2h are substantially similar to FIGS. 2b-2d described above, wherein, however, each of the configurations shown in FIGS. 2f-2h include an additional metal feature 217 adjacent to the metal lines 207 and below the bump structure 203A (see, FIG. 2i, described below). In some illustrative embodiments, the metal feature 217 may be positioned relative to the bump structure 203A such that at least some portions the metal feature 217 are positioned closer to the center 203C of the semiconductor chip 202 than any portion of the bump structure 203A—i.e., substantially in the direction of the shear force 202F. Accordingly, the metal feature 217 may be strategically positioned relative to the bump structure 203A so as to influence the resultant distribution of the shear load 202F through the bump structure 203A and into the metallization system (not shown in FIG. 2f) of the semiconductor chip 202, as will later be described in additional detail.

For example, FIG. 2f schematically depicts an illustrative embodiment of the present disclosure where the metal feature 217 is positioned between the metal line 207 and the chip centerline 202X. The metal feature 217 also has a first edge 217A that is located a distance 217X from the chip centerline 202Y, and a second edge 217B that is located a distance 217Y from the chip centerline 202X. Additionally, the bump structure 203A has a first edge 213A that is a distance 213X from the chip centerline 202Y, and a second edge 213B that is a distance 213Y from the chip centerline 202X. As shown in FIG. 2f, the metal feature 217 is located relative to the bump structure 203A such that the first and second edges 217A, 217B of the metal feature 217 are located closer to chip centerlines 202Y, 202X than the respective first and second edges 213A, 213B of the bump structure 203A. For example, the distance 217X is less than the distance 213X, indicating that first edge 217A of the metal feature 217 is closer to the chip centerline 202Y than is the first edge 213A of the bump structure 203A. Similarly, the distance 217Y is less than the distance 213Y, indicating that second edge 217B of the metal feature 217 is closer to the chip centerline 202X than is the second edge 213B of the bump structure 203A. In this way, the metal feature 217 may act as a structural element that provides some additional support to the area of the metallization system (not shown in FIG. 20 by spreading out the high magnitude loads 218C and/or 218T (see, FIG. 2e) that occur below the edges 213A, 213B of the bump structure 203A, as will be described in further detail with respect to FIG. 2i below.

As with FIG. 2f described above, FIGS. 2g-2h schematically depict additional embodiments of the presently disclosed subject matter, where a metal feature 217 is positioned adjacent to one or more metal lines 207, and where the first and second edges 217A, 217B of the metal feature 217 are closer to the chip centerlines 202Y, 202X than are the respective first and second edges 213A, 213B of the bump structure 203A.

The metal features 217 of FIGS. 2f-2h may be formed using the same photolithography, patterning, and material deposition techniques used to form the metal lines 207 making up the overall circuit layout (not shown) of the semiconductor chip 202—techniques that are well known to those having ordinary skill in the art. For example, in those embodiments of the present disclosure where the metal features 217 may be made up of, for example, copper or copper alloy materials, the metal features 217 may be formed using a damascene technique, wherein openings may be formed in the respective metallization layer, a seed layer may be deposited inside of the openings, and the openings filled using a suitable material deposition technique, such as electrochemical plating and the like. Other schemes which do not otherwise interrupt the normal processing flow of the back end of line (BEOL) metallization structures may also be utilized.

Furthermore, while, in certain illustrative embodiments, the metal features 217 may be formed as elements that are separate and apart from the metal lines 207, in at least some embodiments of the present disclosure, the patterning process used to form the metal lines 207 may be adjusted so that the metal features 217 may be formed as an integral part of one or more of the metal lines 207. For example, the metal features 217 shown in FIGS. 2f-2g may be formed by adjusting the pattern used to form the metal lines 207 so that the width 207W of the metal line 207 is locally increased by a width 217W of the metal feature 217 in an area around the bump structure 203A, such that the increased width portion 217W of the line 207 is substantially oriented along the line of the shear force 202F—i.e., toward the center 202C of the semiconductor chip 202. Furthermore, a length 217L of the metal feature 217 may be similarly adjusted relative to the bump structure 203A so that the edges 217A, 217B and 213A, 213B of the metal feature 217 portion of the metal line 207 having an increased width 217W and length 217L meet the relative edge position criteria previously described.

FIG. 2i schematically illustrates a representative cross-sectional view of the bump structures 203A, metal lines 207 and metal features 217 of FIGS. 2f-2h. In the illustrative embodiment shown in FIG. 2i, the bump structure 203A is a “dummy” bump structure, as there is no contact pad below the bump structure 203A that might incorporate the bump structure 203A into the overall circuit layout (not shown) of the semiconductor chip 202 (see, e.g., FIGS. 1d and 2e). However, it should be appreciated that a contact pad, such as the contact pad 205 of FIG. 2e, may be conveniently incorporated into any of the embodiments disclosed herein. In some embodiments, the metal feature 217 may be positioned in the same metallization layer 204B of the metallization system 204 as the metal line 207. Furthermore, in certain embodiments, such as the embodiment illustrated in FIG. 2i, the metal feature 217 may be immediately adjacent to and in contact with the metal line 207, such that the metal feature 217 can be formed as an integral part of the metal line 207, as previously described.

As shown in FIG. 2i, the metal feature 217 may be positioned in the metallization layer 204B substantially below the edges 213A, 213B of the bump structure 203A. Furthermore, in at least some illustrative embodiments, the edges 217A, 217B of the metal feature 217 may extend beyond the point of the highest compressive load 218C that is induced in the metallization system 204 at the edges 213A, 213B of the bump structure 203A by a distance 227. Accordingly, the compressive load 218C occurring at the edges 213A, 213B of the bump structure 203A may thereby be spread across the width 217W and/or the length 217L of the metal feature 217 so that the higher magnitude compressive load 218C is reduced to a lower magnitude distributed compressive load 228C on the underlying metallization layers, such as the metallization layer 204C. In those illustrative embodiments of the present disclosure where the metallization layer 204C below the metal feature 217 is made up of a lower strength low-k or ULK dielectric material, the distributed compressive load 228C may result in a stress that is below threshold at which a stress-induced failure, such as a crack 209, may form in the metallization layer 204C. Accordingly, in at least some embodiments, a metal feature in accordance with the presently disclosed subject matter, such as the metal feature 217, may be positioned in or below a metallization layer which may be made up of dielectric material having sufficient mechanical strength to withstand the higher magnitude compressive load 218C (such as a “traditional” dielectric material as previously described), and above a metallization layer having a lower mechanical strength, e.g., a low-k or ULK dielectric material, which may nonetheless be sufficiently strong enough to withstand the lower magnitude distributed compressive load 228C.

Depending on the overall design and device integration requirements, the distance 227 by which the edges 217A, 217B extend beyond the edges 213A, 213B may be adjusted as required so as to meet the expected loading criteria on the bump structures 203A during the bump reflow process. For example, in some embodiments, the distance 227 may be in the range of 2-10 μm, whereas in certain embodiments the distance 227 may be at least 5 μm so that the load-spreading advantages of the metal feature 217 described above may be realized. It should be noted, however, that in specific embodiments, the distance 227 may be minimized so as to reduce the overall impact that the size of the metal feature 217 may have on the real estate that may be available within the metallization system 204 to form the requisite circuit layout (not shown) for the semiconductor chip 202.

FIGS. 2j-2k schematically illustrate further illustrative embodiments of the present disclosure wherein the metal feature 217 may not be utilized in conjunction with a metal line 207.

FIG. 2j schematically depicts a plan view of the spatial relationship between a metal feature 217 of a metallization system (not shown) and a representative bump structure 203A in accordance with one illustrative embodiment disclosed herein. In contrast to the previously described embodiments shown in FIGS. 2f-2i, the embodiment shown in FIG. 2j does not include a metal line, such as the metal line 207 of FIGS. 2f-2i, in the metallization system (not shown) of the semiconductor chip 202. Instead, a separate and discrete metal feature 217 may be positioned adjacent to and below the bump structure 203A in a manner similar to that previously described. For example, in those embodiments where there are no metal lines proximately located to the bump structure 203A—such as the previously described metal lines 207 illustrated in FIGS. 2f-2i—the metal feature 217 alone may be utilized to substantially spread out the loads induced by the bump structure 203A on the underlying metallization system (not shown).

As shown in FIG. 2j, in some illustrative embodiments, the metal feature 217 may have a length 217L, a width 217W, and edges 217A-D. Additionally, the metal feature 217 may be positioned relative to the bump structure 203A such that at least a portion of the metal feature 217 is located closer to the center 202C of the semiconductor chip 202 than any portion of the bump structure 203A—i.e., substantially along the line of the shear force 202F, as previously described. Furthermore, the edges 217A and 217B of the metal feature 217 may be positioned closer to the chip centerlines 202Y and 202X, respectively, than the respective edges 213A and 213B of the bump structure 203A so as to meet the relative spacing criteria described above. Additionally, in at least some embodiments of the present disclosure, the edges 217C and 217D of the metal feature 217 may be positioned at partially below the bump structure 203A so that the previously described load-spreading advantages of the metal feature 217 may be obtained, as will be described in further detail below.

FIG. 2k schematically illustrates a cross-sectional view of the bump structure 203A and metal feature 217 shown in FIG. 2j and described above. As shown in FIG. 2k, the metal feature 217 is located in the metallization layer 204B below the bump structure 203A and the last metallization layer 204A. Furthermore, the edges 217C, 217D of the metal feature 217 are positioned below the bump structure 203A, and the edges 217A, 217B extend beyond the edges 213A, 213B of the bump structure 203A by a distance 227. As with the embodiments illustrated in FIG. 2i above, the compressive load 218C induced by the bump structure 203A in the metallization system 204 below the edges 213A, 213B may therefore be spread out over the length 217L and/or the width 217W of the metal feature 217 to a reduced level, as indicated by the distributed compressive load 228C on the metallization layer 204C. Accordingly, in those embodiments where the metallization layer 204C is made up of a low-strength dielectric material, such as a low-k or ULK dielectric material, the lower magnitude distributed compressive load 228C may not lead to a local failure of the metallization layer 204C, such as a crack 209, and a commensurate white bump occurrence.

As a result, the subject matter disclosed herein provides designs for various configurations of metal features that may be used in the metallization system of a semiconductor chip below and/or in the vicinity of bump structures that are located in those areas of the chip where the coefficient of thermal expansion differentials between the chip and a carrier substrate may be the greatest. Accordingly, the metal features of the present disclosure may serve to eliminate, or at least mitigate, the effects of semiconductor chip and carrier substrate interactions during the chip packaging process, thereby reducing the likelihood of white bump occurrences.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor chip, comprising:
a bump structure above a first metallization layer of a metallization system of said semiconductor chip; and
a metal feature in said first metallization layer, wherein at least a first portion of said metal feature is located closer to a center of said semiconductor chip than any portion of said bump structure, and at least a second portion of said metal feature is positioned below said bump structure.

2. The semiconductor chip of claim 1, wherein said bump structure comprises a first bump edge that is oriented toward a first chip centerline, said metal feature comprises a first feature edge that is oriented toward said first chip centerline, said first bump edge is a first bump distance from said first chip centerline, said first feature edge is a first feature distance from said first chip centerline, and said first feature distance is less than said first bump distance.

3. The semiconductor chip of claim 2, wherein said bump structure comprises a second bump edge that is oriented toward a second chip centerline, said metal feature comprises a second feature edge that is oriented toward said second chip centerline, said second bump edge is a second bump distance from said second chip centerline, and said second feature edge is a second feature distance from said second chip centerline that is less than said second bump distance.

4. The semiconductor chip of claim 1, wherein said bump structure comprises one of a solder bump and a pillar bump.

5. The semiconductor chip of claim 1, wherein said first metallization layer is above a second metallization layer of said metallization system, said second metallization layer comprising a low-k dielectric material having a dielectric constant of approximately 3.0 or lower.

6. The semiconductor chip of claim 1, wherein said bump structure is in electrical contact with a bond pad in a last metallization layer of said metallization system.

7. The semiconductor chip of claim 1, wherein said metal feature is part of a conductive line of a circuit formed on said semiconductor chip.

8. The semiconductor chip of claim 1, wherein said metal feature is electrically connected to said bump structure.

9. The semiconductor chip of claim 2, wherein said second distance is at least 5 μm less than said second distance.

10. The semiconductor chip of claim 1, wherein said metal feature comprises copper.

11. The semiconductor chip of claim 1, wherein said bump structure is proximate a corner of said semiconductor chip.

12. A semiconductor chip, comprising:
a first metallization layer of a metallization system of said semiconductor chip, said first metallization layer comprising a metal feature, and said metal feature comprising an edge that is a first distance from a centerline of said semiconductor chip;
a second metallization layer of said metallization system, wherein said second metallization layer is below said first metallization layer, said second metallization layer comprising a low-k dielectric material having a dielectric constant of approximately 3.0 or lower; and
a bump structure above a last metallization layer of said metallization system, wherein said last metallization layer is above said first metallization layer, said bump structure is positioned above at least a portion of said metal feature, said bump structure comprising an edge that is a second distance from said centerline, wherein said first distance is less than said second distance.

13. The semiconductor chip of claim 12, wherein said metal feature comprises a conductive line.

14. The semiconductor chip of claim 13, wherein said conductive line comprises a line portion having a first width and a feature portion have a second width that is greater than said first width.

15. The semiconductor chip of claim 12, further comprising a bond pad in said third metallization layer, wherein said bond pad is in electrical contact with said bump structure.

16. The semiconductor chip of claim 12, wherein said metal feature is electrically connected to said bump structure.

17. A method, comprising:
forming a metal feature in a first metallization layer of a metallization system of a semiconductor chip, wherein said metal feature comprises an edge that is a first distance from a centerline of said semiconductor chip; and
forming a bump structure above a last metallization layer of said metallization system, wherein said bump structure is formed above at least a portion of said metal feature and comprises an edge that is a second distance from said centerline that is greater than said first distance.

18. The method of claim 17, wherein forming said metal feature comprises forming said metal feature above a second metallization layer comprising a low-k dielectric material having a dielectric constant of approximately 3.0 or lower.

19. The method of claim 17, wherein forming said metal feature comprises forming said metal feature as part of a conductive line.

20. The method of claim 19, wherein forming said metal feature as part of a conductive line comprises forming a line portion of said conductive line with a first width and a feature portion of said conductive line with a second width that is greater than said first width.
